(19) United States
(12) Patent Application Publication
(10) Pub. No.: US 2010/0173212 A1
(43) Pub. Date: Jul. 8, 2010

(54) FUEL CELL DEGRADATION DETECTING APPARATUS AND FUEL CELL SYSTEM

(76) Inventors: Kiyoshi SENOUE, Yokohama-shi (JP); Hidenori Suzuki, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/727,077

(22) Filed: Mar. 18, 2010

Related U.S. Application Data
(63) Continuation of application No. PCT/JP2008/067034, filed on Sep. 19, 2008.

(30) Foreign Application Priority Data
Sep. 28, 2007 (JP) 2007-256235

(51) Int. Cl. H01M 8/04; G01R 27/08

(52) U.S. Cl. 429/432; 324/713

(57) ABSTRACT

In a fuel cell system, a load control unit causes transistor elements to be operated at a timing of every predetermined elapsed periods, so that specific currents having α and 2α amperes are output. In a degradation detection unit, output voltages Va, Vb are obtained from the α and 2α amperes, an inclination R(=dv/dI) corresponding to output a resistance Rdmfc is acquired from a difference dv between the output voltages Va, Vb, and an open circuit voltage OCV is obtained from a voltage (Va+dv) obtained by adding the difference dv to the voltage Va. In a judgment unit, the inclination R(=dv/dI) and the voltage OCV are compared with threshold values, respectively, so that the a detection signal indication a degradation of a fuel cell power generation unit is output. Thus, it is possible to detect the cell degradation and to drive a load constantly and stably.

### CROSS-REFERENCE TO RELATED APPLICATIONS

This is a Continuation Application of PCT Application No. PCT/JP2008/067034, filed Sep. 19, 2008, which was published under PCT Article 21(2) in Japanese.

This application is based upon and claims the benefit of priority from prior Japanese Patent Application No. 2007-256235, filed Sep. 28, 2007, the entire contents of which are incorporated herein by reference.

### BACKGROUND OF THE INVENTION

1. Field of the Invention

The present invention relates to a fuel cell degradation detecting apparatus for detecting degradation of a fuel cell and to a fuel cell system.

2. Description of the Related Art

Miniaturization of electronic devices such as mobile phones and personal digital assistants (PDA) is remarkable. With the miniaturization of these electronic devices, the use of a fuel cell as a power supply is attempted. The fuel cell can generate electric power only by supplying a fuel and air, and hence it has an advantage that the replenishment of the fuel only enables the continuous generation of the electric power. Therefore, if the miniaturization of the fuel cell can be realized, the fuel cell is expected as a power supply for small electronic devices.

Thus, in recent years, as the fuel cells, much attention has been paid to direct methanol fuel cells (which will be referred to as DMFCs hereinafter). The DMFCs are classified depending on liquid fuel supply systems, which are an active system such as a gas supply type or a liquid supply type and a passive system such as an internal vaporization type where a liquid fuel in a fuel reservoir unit is vaporized in a cell to supply the vaporized fuel to a fuel electrode.

In these fuel cells, the cell of the passive system is particularly advantageous to the miniaturization of the DMFC.

Heretofore, a DMFC of such a passive system has been disclosed in a booklet of International Publication No. 2005/112172. In the DMFC of the passive system, a configuration has been contrived in which a membrane electrode assembly (a fuel cell) having a fuel electrode, an electrolyte membrane and an air electrode is arranged above a fuel reservoir unit comprising a box-like container made of a resin.

Further, in PCT National Publication No. 2005-518646, JP-A 2006-085952 (KOKAI) and U.S. Patent Publication No. 2006/0029851, there are disclosed DMFCs each having a configuration where a fuel cell and a fuel reservoir unit are connected with each other through a flow path. In the DMFC disclosed in each of PCT National Publication No. 2005-518646, JP-A 2006-085952 (KOKAI) and U.S. Patent Publication No. 2006/0029851, a liquid fuel supplied from the fuel reservoir unit is forwarded to the fuel cell through the flow path, and a supply amount of the liquid fuel can be adjusted based on, e.g., a shape or a diameter of the flow path. Particularly, in the DMFC disclosed in JP-A 2006-085952 (KOKAI), the liquid fuel is supplied from the fuel reservoir unit to the flow path by a pump. In addition, this JP-A 2006-085952 (KOKAI) describes that an electric field forming unit which forms an electroosmotic flow is used in the flow path, in place of the pump. Furthermore, in U.S. Patent Publication No. 2006-0029851, it is described that a liquid fluid or the like is supplied by using an electroosmotic flow pump.

Meanwhile, when such an EDMFC is continuously operated for over a long period, the entire cell expands due to, for examples, a gas produced in the cell, delamination may occur in a collector unit used for an anode or a cathode. In addition, degradation (poisoning) of a catalyst may also occur. Due to these causes, a cell output may be rapidly lowered.

Therefore, when the DMFC is continuously used as a driving power supply of load in this state, electric power supplied to the load becomes unstable, resulting in a problem that the load cannot be stably driven.

### BRIEF SUMMARY OF THE INVENTION

An object of the present invention is to provide the a cell degradation detecting apparatus and the fuel cell system that can detect the cell degradation and constantly stably drive the load can be provided.

According to an aspect of the present invention, there is provided an apparatus for detecting a fuel cell degradation comprising:

a fuel cell main body having a fuel cell power generation unit;

a cell output acquisition unit which allows the fuel cell power generation unit to output a first electric current and a second electric current which is double the first electric current;

a degradation detection unit which detects at least one of an output resistance and an open circuit voltage of the fuel cell power generation unit by using an output voltage obtained based on the first and second electric currents in a state that the cell output acquisition unit allows the fuel cell power generation unit to output the first and second electric currents; and

a degradation judgment unit which judges degradation of the fuel cell power generation unit by using at least one of the output resistance and the open circuit voltage of the fuel cell power generation unit detected by the degradation detection unit.

In the apparatus described above, the degradation detection unit obtains an output voltage Va and an output voltage Vb associated with the first and second electric currents in a state that the fuel cell power generation unit is allowed to output the first and second electric currents, and detects at least one of an inclination R(=dv/dI) corresponding to the output resistance of the fuel cell power generation unit which is obtained from a difference voltage dv of the output voltages Va and Vb and a difference current dI of the first and second electric currents and an open circuit voltage OCV obtained from (Va+dv) acquired by adding the voltage difference dv to the output voltage Va.

In the apparatus described above, the apparatus, when a predetermined threshold value is set with respect to at least one of the inclination R and the open circuit voltage OCV detected by the degradation detection unit and the inclination R exceeds the set threshold value or the open circuit voltage OCV falls below the set threshold value, the degradation judgment unit determines the degradation of the fuel cell power generation unit.

According to an another aspect of the present invention, there is provided a fuel cell system comprising:

a fuel cell main body having a fuel cell power generation unit, a fuel reservoir unit that contains a liquid fuel, and a fuel transfer control unit which controls supply of the fuel to the fuel cell power generation unit from the fuel reservoir unit;

a cell output acquisition unit which allows the fuel cell power generation unit to output a first electric current and a second electric current that is double the first electric current;

a degradation detection unit which detects at least one of an output resistance and an open circuit voltage of the fuel cell power generation unit by using an output voltage obtained based on the first and second electric currents in a state that the cell output acquisition unit allows the fuel cell power generation unit to output the first and second electric currents; and

a degradation judgment unit which judges the degradation of the fuel cell power generation unit based on at least one of the output resistance and the open circuit voltage of the fuel cell power generation unit detected by the degradation detection unit,

wherein a fuel supply amount for the fuel cell power generation unit provided by the fuel transfer control unit is controlled in accordance with the degradation judgment made by the degradation judgment unit.

In the system described above, the degradation detection unit obtains an output voltage Va and an output voltage Vb associated with the first and second electric currents in a state that the fuel cell power generation unit is allowed to output the first and second electric currents, and detects at least one of an inclination R(=dv/dI) corresponding to the output resistance of the fuel cell power generation unit which is obtained from a difference voltage dv of the output voltages Va and Vb and a difference current dI of the first and second electric currents and an open circuit voltage OCV obtained from (Va+dv) acquired by adding the voltage difference dv to the output voltage Va.

In the system described above, when a predetermined threshold value is set with respect to at least one of the inclination R and the open circuit voltage OCV detected by the degradation detection unit and the inclination R exceeds the set threshold value or the open circuit voltage OCV falls below the set threshold value, the degradation judgment unit determines the degradation of the fuel cell power generation unit and outputs a degradation detection signal.

In the system described above, a fuel supply amount for the fuel cell power generation unit provided by the fuel transfer control unit is increased in accordance with the degradation judgment of the degradation judgment unit to control an electric-generating capacity of the fuel cell power generation unit.

In the system described above, a fuel supply amount for the fuel cell power generation unit provided by the fuel transfer control unit is reduced in accordance with the degradation judgment of the degradation judgment unit to control an electric-generating capacity of the fuel cell power generation unit.

In the system described above, the fuel supply control unit comprises a pump which is used for transferring the fuel to the fuel cell power generation unit or a fuel cutoff valve which enables cutting off supply of a liquid fuel to the fuel cell main body.

### BRIEF DESCRIPTION OF THE SEVERAL VIEWS OF THE DRAWING

FIG. 1 is a block diagram showing a schematic configuration of a fuel cell system according to a first embodiment of the present invention;

FIG. 2 is a cross-sectional view schematically showing a fuel cell main body depicted in FIG. 1;

FIG. 3 is a perspective view schematically showing a fuel distribution mechanism incorporated in the fuel cell main body depicted in FIG. 2;

FIG. 4 is a circuit diagram showing a constant current load unit depicted in FIG. 1;

FIG. 5 is a graph showing a relationship between an output current and an output voltage for explaining an operation of a degradation detection unit depicted in FIG. 1; and

FIG. 6 is a circuit diagram showing an equivalent circuit of a fuel cell power generation unit depicted in FIG. 1.

### DETAILED DESCRIPTION OF THE INVENTION

A fuel cell degradation detecting apparatus and a fuel cell system according to an embodiment of the present invention will now be described hereinafter with reference to the drawings.

### First Embodiment

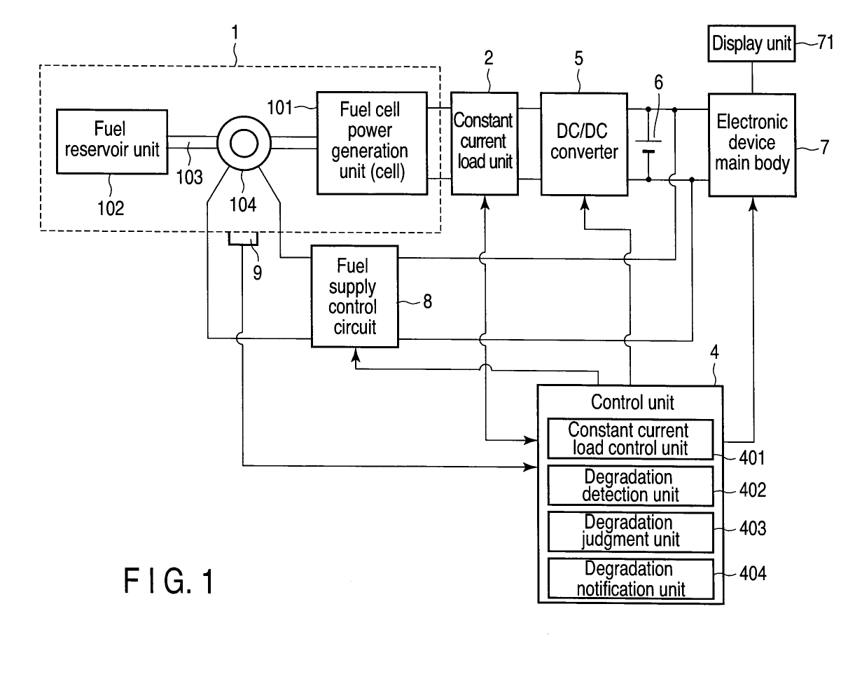

FIG. 1 shows a schematic configuration of a fuel cell system applied to a first embodiment of the present invention.

In FIG. 1, reference numeral 1 denotes a fuel cell main body (a DMFC), and this fuel cell main body 1 has a fuel cell power generation unit (a cell) 101 that forms an electrogenic unit which generates electric power, a fuel reservoir unit 102 that contains a liquid fuel, a flow path 103 that connects the fuel reservoir unit 102 with the fuel cell power generation unit (the cell) 101, and a pump 104 as a fuel supply control unit that is used for transferring the liquid fuel to the fuel cell power generation unit (the cell) 101 from the fuel reservoir unit 102.

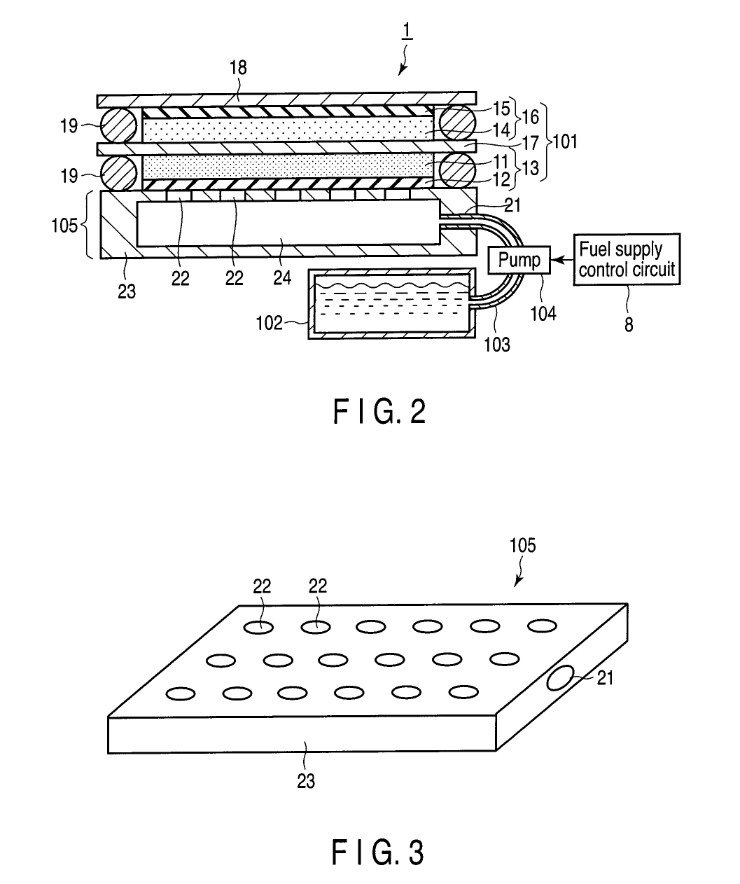

FIG. 2 is a cross-sectional view showing the fuel cell main body 1 depicted in FIG. 1 in more detail.

As shown in FIG. 2, the fuel cell power generation unit 101 has a membrane electrode assembly (MEA). This membrane electrode assembly (MEA) is formed of an anode (a fuel electrode) 13 having an anode catalytic layer 11 and an anode gas diffusion layer 12, a cathode (an air electrode/oxidant electrode) 16 having a cathode catalytic layer 14 and a cathode gas diffusion layer 15, and proton (hydrogen ion) conducting electrolyte membrane 17 sandwiched between the anode catalytic layer 11 and the cathode catalytic layer 14.

Here, as a catalyst contained in the anode catalytic layer 11 and the cathode catalytic layer 14, there is, e.g., a simple substance of platinum group elements such as Pt, Ru, Rh, Ir, Os or Pd or an alloy that contains a platinum group element. It is preferable to use, e.g., Pt—Ru or Pt—Mo that has strong resistance properties against methanol or a carbon monoxide for the anode catalytic layer 11. It is preferable to use, e.g., Pt or Pt—Ni for the cathode catalytic layer 14. However, the catalyst is not restricted to these substances, and various kinds of substances having catalytic activity can be used. The catalyst may be one of a supported catalyst using a conducting support such as a carbon material and a non-supported catalyst.

As a proton-conducting material that forms the electrolyte membrane 17, there is, e.g., a fluorinated resin such as a perfluorosulfonic acid polymer having a sulfonic group (Nafion (a trade name, manufactured by DuPont) or Flemion (a trade name, manufactured by Asahi Glass Co., Ltd.), an organic type material such as a hydrocarbon-based resin having a sulfonic group, or an inorganic type material such as a tungsten acid or a phosphotungstic acid. However, the proton-conducting electrolyte membrane 17 is not restricted to these materials.

The anode gas diffusion layer 12 laminated on the anode catalytic layer 11 serves a function of uniformly supplying the fuel to the anode catalytic layer 11 and also serves a function as a collector for the anode catalytic layer 11. The cathode gas diffusion layer 15 laminated on the cathode catalytic layer 14 serves a function of uniformly supplying an oxidant to the cathode catalytic layer 14 and also serves a function as a collector for the cathode catalytic layer 14. Each of the anode gas diffusion layer 12 and the cathode gas diffusion layer 15 is formed of a porous base material.

A conductive layer is laminated on the anode gas diffusion layer 12 or the cathode gas diffusion layer 15 as required. As such a conductive layer, a mesh, a porous film or a thin film formed of a conductive metal material such as Au is used. Rubber O-rings 19 are interposed between the electrolyte membrane 17 and a later-described fuel distribution mechanism 105 and between the electrolyte membrane 17 and a cover plate 18, and these O-rings avoid fuel leakage or oxidant leakage from the fuel cell power generation unit 101.

The cover plate 18 has an opening (not shown) from which air as the oxidant is taken in. A moisture layer or a surface layer is arranged between the cover plate 18 and the cathode 16 as required. The moisture layer is impregnated with part of water generated in the cathode catalytic layer 14 to suppress evaporation of water and to facilitate uniform diffusion of air to the cathode catalytic layer 14. The surface layer adjusts a fetch amount of air and has a plurality of air introducing openings whose number or size is adjusted in accordance with a fetch amount of air.

The fuel distribution mechanism 105 is arranged on the anode (the fuel electrode) 13 side of the fuel cell power generation unit 101. The fuel reservoir unit 102 is connected to the fuel distribution mechanism 105 through the flow path 103 for a liquid fuel like a pipe.

The fuel reservoir unit 102 contains the liquid fuel usable in the fuel cell power generation unit 101. As the liquid fuel, there is a methanol fuel such as an aqueous methanol solution having various concentrations or pure methanol. The liquid fuel is not necessarily restricted to the methanol fuel. The liquid fuel may be, e.g., an ethanol fuel such as an aqueous ethanol solution or pure ethanol, a propanol fuel such as an aqueous propanol solution or pure propanol, a glycol fuel such as an aqueous glycol solution or pure glycol, dimethyl ether, a formic acid or any other liquid fuel. In any case, the fuel reservoir unit 102 contains the liquid fuel usable in the fuel cell power generation unit 101.

The liquid fuel is introduced into the fuel distribution mechanism 105 from the fuel reservoir unit 102 through the flow path 103. The flow path 103 is not restricted to a pipe which is independent from the fuel distribution mechanism 105 or the fuel reservoir unit 102. For example, when laminating and integrating the fuel distribution mechanism 105 and the fuel reservoir unit 102, the flow path 103 may be a liquid fuel flow path which connects these members. It is good enough to connect the fuel distribution mechanism 105 to the fuel reservoir unit 102 via the flow path 103.

Here, as shown in FIG. 3, the fuel distribution mechanism 105 includes a fuel distribution plate 23 having at least one fuel inlet opening 21 from which the liquid fuel flows in through the flow path 103 and a plurality of fuel outlet openings 22 from which the liquid fuel or its vaporized substance is discharged. As shown in FIG. 2, a void portion 24 that serves as a path for the liquid fuel introduced from the fuel inlet opening 21 is provided in the fuel distribution plate 23. Each of the plurality of fuel outlet openings 22 is directly connected with the void portion 24 which functions as the fuel path.

The liquid fuel introduced into the fuel distribution mechanism 105 from the fuel inlet opening 21 enters the void portion 24 to be led to the plurality of fuel outlet openings 22 via the void portion 24 that functions as the fuel path. For example, a gas-liquid separator (not shown) which allows a vaporized component of the liquid fuel alone to pass therethrough but does not allow a liquid component to pass therethrough may be arranged in each of the plurality of fuel outlet openings 22. As a result, the vaporized component of the liquid fuel is supplied to the anode (the fuel electrode) 13 of the fuel cell power generation unit 101. It is to be noted that the gas-liquid separator may be disposed as a gas-liquid separator film or the like between the fuel distribution mechanism 105 and the anode 13. The vaporized component of the liquid fuel is discharged from the plurality of fuel outlet openings 22 toward a plurality of positions of the anode 13.

The plurality of fuel outlet openings 22 are provided in a surface of the fuel distribution plate 23 facing the anode 13 so that the fuel can be supplied to the entire fuel cell power generation unit 101. Although two or above can suffice as the number of the fuel outlet openings 22, it is preferable to form the plurality of fuel outlet openings 22 in such a manner that 0.1 to 10 fuel outlet openings are present per cm² in terms of uniforming a fuel supply amount within a surface of the fuel cell power generation unit 101.

The pump 104 is inserted in the flow path 103 which connects the fuel distribution mechanism 105 to the fuel reservoir unit 102. This pump 104 is not a circulation pump which circulates the fuel but a fuel supply pump which transfers the liquid fuel to the fuel distribution mechanism 105 from the fuel reservoir unit 102. When such a pump 104 supplies the liquid fuel as needed, controllability with respect to a fuel supply amount can be enhanced. As this pump 104, it is preferable to use, e.g., a rotary vane pump, an electroosmotic pump, a diaphragm pump or a squeeze pump in terms of the fact that a small amount of liquid fuel can be supplied with good controllability and a reduction in size and weight is possible. The rotary vane pump rotates vanes by a motor to supply the liquid. The electroosmotic pump uses a sintered porous body such as a silica that causes an electroosmotic phenomenon. The diaphragm pump drives a diaphragm by an electric magnet or piezoelectric ceramics to supply the liquid. The squeeze pump brings pressure on the flexible fuel flow path to squeeze and supply the fuel. Of these pumps, it is more preferable to use the electroosmotic pump or the diaphragm pump having the piezoelectric ceramics in terms of, e.g., driving power or a size.

Moreover, a later-described fuel supply control circuit 8 is connected with the pump 104 to control an operation of the pump 104. This point will be explained later.

In such a configuration, the liquid fuel contained in the fuel reservoir unit 102 is transferred through the flow path 103 by the pump 104 to be supplied to the fuel distribution mechanism 105. Additionally, the fuel discharged from the fuel distribution mechanism 105 is supplied to the anode (the fuel electrode) 13 of the fuel cell power generation unit 101. In the fuel cell power generation unit 101, the fuel diffuses in the anode gas diffusion layer 12 to be supplied to the anode catalytic layer 11. When a methanol fuel is used as the liquid fuel, an internal reforming reaction of methanol represented by the following Expression (1) occurs.

It is to be noted that, when pure methanol is used as the methanol fuel, wafer produced in the cathode catalytic layer 14 or water in the electrolyte membrane 17 is reacted with methanol to cause the internal reforming reaction represented by Expression (1) or any other reaction mechanism which does not require water is utilized to cause the internal reforming reaction.

CH₃OH+H₂O→CO₂+6H⁺+6e⁻ (1)

Electrons (e⁻) produced by this reaction are led to the outside through the collector, supplied to a load side as a so-called output, and then led to the cathode (the air electrode) 16. Further, protons (H⁺) generated by the internal reforming reaction represented by Expression (1) are led to the cathode 16 via the electrolyte membrane 17. Air is supplied as an oxidant to the cathode 16. The electrons (e⁻) and the protons (H⁺) which have reached the cathode 16 react with oxygen in air in the cathode catalytic layer 14 in accordance with the following Expression (2), and water is produced with this reaction.

6e⁻+6H⁺+(3/2)O₂→3H₂O (2)

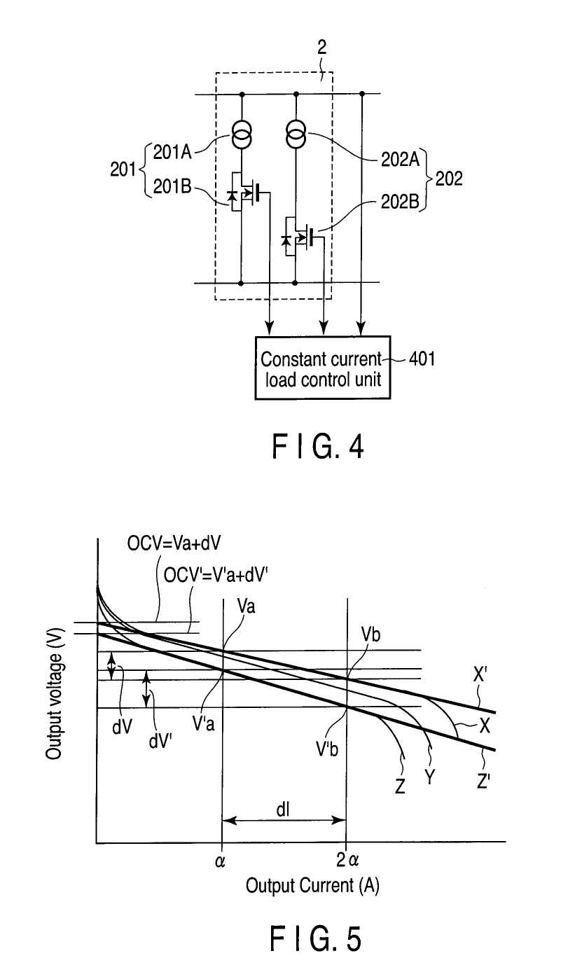

As shown in FIG. 1, to the fuel cell power generation unit (the cell) 101 of the fuel cell main body 1 is connected a constant current load unit 2 as a cell output acquisition unit to which electric power from the fuel cell power generation unit (the cell) 101 is supplied. In this constant current load unit 2, as shown in FIG. 4, a first constant current load circuit 201 formed of a series circuit including a constant current load 201A and a transistor element 201B and a second constant current load circuit 202 formed of a series circuit including a constant current load 202A and a transistor element 202B are connected in parallel between output terminals of the fuel cell power generation unit 101. The first constant current load circuit 201 outputs a specific current, e.g., a constant current of α amperes from the fuel cell power generation unit 101 through the constant current load 201A based on an operation of the transistor element 201B. Likewise, the second constant current load circuit 202 outputs a constant current of α amperes as a specific current from the fuel cell power generation unit 101 through the constant current load 202A based on an operation of the transistor element 202B. As a result, the constant current of α amperes is output as a first current from the fuel cell power generation unit 101 based on the operation of the first constant current load circuit 201 alone, and the constant current of 2α amperes which is double a amperes is output as a second current from the fuel cell power generation unit 101 when the first and second constant current load circuits 201 and 202 are simultaneously operated. It is desirable for a current value which is 2α amperes output from this constant current load unit 2 to be approximately a half of a maximum electric-generating capacity at the time of an operation initial stage of the fuel cell power generation unit 101.

A control unit 4 is connected to the constant current load unit 2. The detail of the control unit 4 will be described later.

A DC-DC converter (a voltage adjustment circuit) 5 is connected as an output adjustment unit to the fuel cell main body 1 via the constant current load unit 2. This DC-DC converter 5 has a switching element (not shown) and an energy storage element, and it uses the switching element and the energy storage element to store/discharge electric energy generated in the fuel cell main body 1 and generate an output that is produced by boosting a relatively low voltage from the fuel cell main body 1 to a sufficient voltage.

It is to be noted that the standard booster type DC-DC converter 5 has here been explained, but a converter of any other circuit system can also be employed as long as it can perform a boosting operation.

An auxiliary power supply 6 is connected with an output terminal of the DC-DC converter 5. This auxiliary power supply 6 can be charged with an output from the DC-DC converter 5, supplies a current with respect to an instantaneous load fluctuation of an electronic device main body 7, and is used as a driving power supply of the electronic device main body 7 when the fuel cell main body 1 cannot generate power because of a fuel depletion state. As this auxiliary power supply 6, a chargeable/dischargeable secondary battery (e.g., a lithium-ion rechargeable battery (LIB)) or an electric double layer capacitor) is used.

A fuel supply control circuit 8 is connected with the auxiliary power supply 6. This fuel supply control circuit 8 uses the auxiliary power supply 6 as a power supply to control an operation of the pump 104, and it outputs a control signal which is used for driving the pump 104 based on an instruction from the control unit 4, ambient temperature information, operation state information of the electronic device main body 7 and others.

The control unit 4 controls the entire system and has a constant current load control unit 401, a degradation detection unit 402, a degradation judgment unit 403 and a degradation notification unit 404. The constant current load control unit 401 controls operations of the transistor elements 201B and 202B of the constant current load unit 2, and it first actuates the transistor element 201B alone to output a constant current of α amperes from the fuel cell power generation unit 101 by using the first constant current load circuit 201 and then actuates the transistor elements 201B and 202B at the same time to output a constant current of 2α amperes from the fuel cell power generation unit 101 by using the first and second constant current load circuits 201 and 202. This constant current load control unit 401 actuates the constant current load unit 2 every fixed time to execute degradation detection.

The degradation detection unit 402 detects degradation of the fuel cell power generation unit 101 in a state that the fuel cell power generation unit 101 outputs the specific currents of α amperes and 2α amperes.

A concept of the degradation detection of the fuel cell will now be briefly described.

As one of characteristics of the fuel cell, there is I-V characteristic. As shown in FIG. 5, this I-V characteristic is obtained by measuring an output voltage (V) when an output current (A) of the fuel cell is changed, and it can be represented by a characteristic curve X. When the fuel cell is continuously used, this characteristic curve X changes like characteristic curves Y and Z in the drawing with passage of a utilization period, and it changes its inclination in particular.

Considering the characteristic curve X, when this characteristic curve X is approximated by a linear function, the following expression can be obtained.

Vo=Rdmfc×Io+OCV

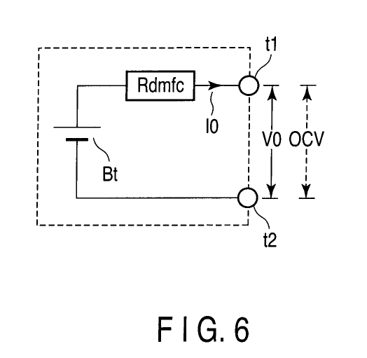

Here, an equivalent circuit of the fuel cell can be represented by a circuit obtained by connecting a cell main body Bt and an output resistance Rdmfc in series between output terminals t1 and t2 as depicted in FIG. 6, and Vo is an output voltage generated between the output terminals t1 and t2, Io is an output current output from the cell main body Bt, Rdmfc is an output resistance of the fuel cell, and OCV (Open Circuit Voltage) is an open circuit voltage in this equivalent circuit. It is to be noted that the open circuit voltage OCV is not an actual open circuit voltage of the fuel cell and it is a virtual open circuit voltage at the time of approximation.

Next, in FIG. 5, the characteristic curve X is regarded as a straight line X′ indicated by a thick line, and an output voltage Va when the specific current of α amperes is flowed as an output current Io of the fuel cell and an output voltage Vb when the specific current of 2α amperes is flowed as the same are obtained, respectively. Furthermore, a voltage difference dv between these output voltage Va and Vb is obtained, and an inclination R(=dv/dI) is acquired from this voltage difference dv and dI(2α−α). This inclination R corresponds to the output resistance Rdmfc. Moreover, (Va+dv) obtained by adding the voltage difference dv to the output voltage Va when the specific current of α amperes is flowed corresponds to a point where an extended line of the straight line X′ crosses an output voltage (V) axis, and an output voltage V at this point corresponds to the open circuit voltage OCV.

Incidentally, in other words, in regard to this (virtual) open circuit voltage, when output characteristics of the fuel cell satisfy “output voltage−−output resistance×output voltage+virtual open circuit voltage”, the following expression can be attained:

dI=2α−α

Namely, the following expression can be achieved:

dI=α

Additionally, the following expression can be attained:

dI−α=0

An output 0A (zero ampere) is provided. When this is determined as an open state and Va−Vb=dV is achieved, the virtual open circuit voltage becomes as follows:

Va+dV

Likewise, for example, the characteristic curve Z shown in FIG. 5 (which represents a curve when the utilization period further passes) is also regarded as a straight line Z′ indicated by a thick line, an output voltage Va′ when the specific current of α amperes is flowed and an output voltage Vb′ when the specific current of 2α amperes is flowed are obtained, and a voltage difference dv′ between these output voltages Va′ and Vb′ is utilized to obtain an inclination R(=dv′/dI) corresponding to the output resistance Rdmfc and an open circuit voltage OCV′ (Va′+dv′).

In this case, the inclination R(=dv′/dI) of the straight line Z′ is obviously larger than the indication R(=dv/dI) of the straight line X′, which means that the output resistance Rdmfc increases. Further, the open circuit voltage OCV′ is obviously lower than the open circuit voltage OCV(Va+dv) of the straight line X′. That is, it is clear that the inclination R and the open circuit voltage OCV vary in accordance with the utilization period of the fuel cell, whereby constantly monitoring the states of the inclination R and the open circuit voltage OCV enables detecting degradation of the fuel cell.

The degradation detection unit 402 performs degradation detection based on such a concept. In this case, the degradation detection unit 402 uses the constant current load control unit 401 to sequentially output the specific currents of α amperes and 2α amperes to the fuel cell power generation unit 101, and it obtains the output voltage Va and the output voltage Vb associated with these specific currents in this state. Then, the inclination R(dv/dI) corresponding to the output resistance Rdmfc is obtained from the difference voltage dv between these output voltages Va and Vb and, at the same time, the open circuit voltage OCV is acquired from (Va+dv) obtained by adding the voltage difference dv to the output voltage Va.

The degradation judgment unit 403 carries out the degradation judgment from the inclination R(=dv/dI) and the open circuit voltage OCV(Va+dv) detected by the degradation detection unit 402. In this state, the degradation judgment unit 403 sets predetermined threshold values with respect to the inclination R and the open circuit voltage OCV, and it determines degradation of the fuel cell power generation unit 101 and outputs a degradation detection signal when the inclination R detected by the degradation detection unit 402 exceeds the preset threshold voltage and the open circuit voltage OCV falls below the preset threshold voltage.

It is to be noted that the inclination R and the open circuit voltage OCV are utilized for the degradation detection in the degradation detection unit 402 and the degradation judgment unit 403, but one of the inclination R and the open circuit voltage OCV may be utilized to judge degradation.

The DC-DC converter 5 and the fuel supply control circuit 8 are connected to the control unit 4.

The operation of the DC-DC converter 5 is forcibly stopped during a period that the control unit 4 executes the degradation detection.

When a degradation determination signal is input from the control unit 4, the fuel supply control circuit 8 increases fuel supply performed by the pump 104 in order to compensate degradation of the fuel cell power generation unit 101. That is, the fuel supply control circuit 8 controls driving of the pump 104 to prolong an ON period of the pump 104 and increases a fuel supply amount for the fuel cell power generation unit 101, thereby compensating a reduction in the electric-generating capacity involved by the degradation of the fuel cell power generation unit 101.

In such a configuration, when an output from the auxiliary power supply 6 is supplied to the fuel supply control circuit 8 as a power supply, the fuel supply control circuit 8 outputs a control signal that is used for performing ON/OFF control over the pump 104 based on ambient temperature information, operation state information of the electronic device main body 7 and others.

As a result, the liquid fuel contained in the fuel reservoir unit 102 is supplied to the fuel cell power generation unit 101 by the pump 104 through the flow path 103, and the fuel cell power generation unit 101 generates a power generation output.

The power generation output from the fuel cell power generation unit 101 is boosted by the DC-DC converter 5 to be supplied to the electronic device main body 7. At the same time, the auxiliary power supply 6 is charged with an output from the DC-DC converter 5. As a result, the electronic device main body 7 uses the electric power supplied from the DC-DC converter 5 as a power supply to be operated.

When a fixed period passes in this state, the constant current load control unit 401 of the control unit 4 actuates the constant current load unit 2 to execute the degradation detection. In this case, the operation of the DC-DC converter 5 is forcibly stopped.

First, the constant current load control unit 401 actuates the transistor element 201B of the constant current load unit 2 to output the constant current of a amperes from the fuel cell power generation unit 101 by using the first constant current load circuit 201. Subsequently, the transistor elements 201B and 202B are simultaneously operated to output the constant current of 2α amperes from the fuel cell power generation unit 101 by using the first and second constant current load circuits 201 and 202. Further, in a state that the specific currents of α amperes and 2α amperes are output, the degradation detection unit 402 obtains the output voltage Va and the output voltage Vb associated with these specific currents, respectively. Furthermore, the inclination R(=dv/dI) corresponding to the output resistance Rdmfc is obtained from the difference voltage dv between these output voltages Va and Vb and, at the same time, the open circuit voltage OCV is acquired from (Va+dv) obtained by adding the voltage difference dv to the output voltage Va.

Subsequently, the inclination R(=dv/dI) and the open circuit voltage OCV detected by the degradation detection unit 402 are supplied to the degradation judgment unit 403 where the degradation judgment is carried out. In this case, in the degradation judgment unit 403, the predetermined threshold values are set with respect to the inclination R and the open circuit voltage OCV, respectively. Moreover, when the inclination R detected by the degradation detection unit 402 exceeds the predetermined threshold value and the open circuit voltage OCV falls below the set threshold value, the degradation of the fuel cell power generation unit 101 is determined, and the degradation detection signal is output.

This degradation detection signal is supplied to the fuel supply control circuit 8. Upon receiving the degradation determination signal from the degradation judgment unit 403, the fuel supply control circuit 8 increases the fuel supply performed by the pump 104 to compensate the degradation of the fuel cell power generation unit 101. That is, the fuel supply control circuit 8 controls driving of the pump 104 to prolong the ON period of the pump 104, whereby the fuel supply amount for the fuel cell power generation unit 101 is increased. As a result, a reduction in the electric-generating capacity involved by the degradation is compensated in the fuel cell power generation unit 101, thereby maintaining the fixed electric-generating capacity.

On the other hand, when the inclination R detected by the degradation detection unit 402 is equal to or below the predetermined threshold value and the open circuit voltage OCV exceeds the set threshold value, the degradation judgment unit 403 determines that the fuel cell power generation unit 101 is in a normal state without degradation, and hence the fuel supply control circuit 8 maintains the ON/OFF control of the pump 104 based on ambient temperature information or operation state information of the electronic device main body 7 as described above.

It is to be noted that, in the above description, when the control unit 4 outputs the degradation determination signal, the fuel supply control circuit 8 controls driving of the pump 104 to prolong the ON period of the pump 104 and the fuel supply amount for the fuel cell power generation unit 101 is increased, but a driving voltage of the pump 104 may be increased (a driving current may be increased) to raise the fuel supply amount for the fuel cell power generation unit 101 in place of this method.

Therefore, when such a configuration is adopted, in a state that the fuel cell power generation unit 101 supplies the generated power to the electronic device main body 7, the constant current load control unit 401 actuates the transistor elements 201B and 202B of the constant current load portion 2 every fixed time to output the specific currents of α amperes and 2α amperes by using the fuel cell power generation unit 101; the degradation detection unit 402 obtains the output voltage Va and the output voltage Vb associated with the specific contents of α amperes and 2α amperes, acquires the inclination R(=dv/dI) corresponding to the output resistance Rdmfc from the difference voltage dv of these output voltages Va and Vb, and obtains the open circuit voltage OCV from (Va+dv) obtained by adding the voltage difference dv to the output voltage Va; and the degradation judgment unit 403 determines the degradation of the fuel cell power generation unit 101 and outputs the degradation detection signal when the inclination R exceeds the predetermined threshold value and the open circuit voltage OCV falls below the set threshold value. Additionally, based on output of this degradation detection signal, the fuel supply control circuit 8 controls driving of the pump 104 to prolong the ON period of the pump 104 and thereby increases the fuel supply amount for the fuel cell power generation unit 101. As a result, since a reduction in the electric-generating capacity of the fuel cell power generation unit 101 involved by the degradation can be compensated and the fixed electric-generating capacity can be maintained, the electric power supplied the electronic device main body 7 does not become unstable and the electronic device main body 7 can be stably continuously driven even if the power generation output from the fuel cell power generation unit 101 is continuously utilized as a driving power supply for the electronic device main body 7 in this state.

### (Modification 1)

In the above-described embodiment, when the degradation determination signal is input, the fuel supply control circuit 8 controls driving of the pump 104 to prolong the ON period of the pump 104 and increases the fuel supply amount for the fuel cell power generation unit 101 to compensate a reduction in the power-generating capacity of the fuel cell power generation unit 101 involved by the degradation. In a modification, as different from the embodiment, the fuel supply control circuit 8 may reduce a fuel supply amount for the fuel cell power generation unit 101 to prolong the life duration of the fuel cell power generation unit 101. When the degradation determination signal is input to the fuel supply control circuit 8, the fuel supply control circuit 8 controls driving of the pump 104 to shorten the ON period of the pump 104 and reduces the fuel supply amount for the fuel cell power generation unit 101 to decrease the electric-generating capacity of the fuel cell power generation unit 101, thereby suppressing a speed of cell degradation. According to such suppression of the speed of cell degradation, even if the degradation of the fuel cell power generation unit 101 begins, an available time can be further prolonged to enable the continuous use.

It is to be noted that the foregoing embodiment adopts the method by which the fuel supply control circuit 8 controls driving of the pump 104 to shorten the ON period of the pump 104 upon output of the degradation determination signal and reduces the fuel supply amount for the fuel cell power generation unit 101. However, a driving voltage of the pump 104 may be lowered (or a driving current may be lowered) to reduce the fuel supply amount for the fuel cell power generation unit 101 in place of this method.

### (Modification 2)

As shown in FIG. 1, a temperature detector 9 is provided to the fuel cell main body 1, and the degradation judgment unit 403 judges degradation. In this degradation judgment, the control unit 4 makes reference to a temperature detected by the temperature detector 9. When it is detected that this detected temperature is a high temperature or a low temperature at which the degradation of the fuel cell power generation unit 101 becomes prominent, the operation of the pump 4 carried out by the fuel supply control circuit 8 is turned off to forcibly stop the power generating operation of the fuel cell power generation unit 101. According to this forced stop of the power generating operation, it is possible to avoid a situation that the degradation of the fuel power generation unit 101 is detected and then the fuel cell power generation unit 101 is further rapidly degraded to the impossibility of regeneration.

### (Modification 3)

For example, when the degradation judgment unit 403 determines the degradation of the fuel cell power generation unit 101, information of this determination may be supplied to the outside. In this modification, a degradation notification unit 404 is provided in the control unit 4 as shown in FIG. 1. When the degradation judgment unit 403 determines the degradation of the fuel cell power generation unit 101, this degradation notification unit 404 generates a degradation notification signal and outputs this degradation notification signal to the electronic device main body 7. A display unit 71 as a notification unit is provided to the electronic device main body 7. The display unit 71 displays the degradation of the fuel cell power generation unit 101, and an LED is used as an illuminant, for example. Of course, a unit that generates sound such as a buzzer may be utilized as the notification unit. According to such degradation notification, since the degradation of the fuel cell power generation unit 101 can be displayed in the display unit 71 of the electronic device main body 7, a user can be rapidly informed of the cell degradation and thereby immediately cope with such a situation.

It is to be noted that the present invention is not restricted to the foregoing embodiment, and it can be modified in many ways without departing from the scope of the invention on the embodying stage. For example, although the degradation detection is carried out every fixed time in the foregoing embodiment, it may be executed when activating the fuel cell power generation unit 101. Further, although the degradation detection unit 402 detects the inclination R(=dv/dI) corresponding to the output resistance Rdmfc and the open circuit voltage OCV, it may detect at least one of the inclination R and the open circuit voltage OCV. Furthermore, although the example where the pump 104 as the fuel transfer control unit is arranged in the flow path 103 which connects the fuel distribution mechanism 105 with the fuel reservoir unit 102 has been described in conjunction with the foregoing embodiment, a fuel cutoff valve may be arranged in series with the pump 104. This fuel cutoff valve is provided to avoid evaporation of the liquid fuel from the pump 104 at the time of, e.g., long-term storage, and it may have a function of the fuel supply control unit, i.e., forcibly cutting off the fuel cutoff valve to forcibly stop supply of the liquid fuel to the fuel cell main body 1 in place of stopping control of the pump 104.

Moreover, the foregoing embodiment includes inventions on the various stages, and appropriately combining a plurality of disclosed constituent requirements enables extracting various inventions. For example, if the problem described in the section “Problem to be Solved by the Invention” can be solved and the effect described in the section “Effect of the Invention” can be obtained even though several constituent requirements are deleted from all constituent requirements disclosed in the embodiment, a configuration obtained by deleting these constituent requirements can be extracted as an invention.

According to the present invention, the fuel cell degradation detecting apparatus and the fuel cell system that can rapidly detect the cell degradation and constantly stably drive the load can be provided.

What is claimed is:

1. An apparatus for detecting a fuel cell degradation comprising:
a fuel cell main body having a fuel cell power generation unit;
a cell output acquisition unit which allows the fuel cell power generation unit to output a first electric current and a second electric current which is double the first electric current;
a degradation detection unit which detects at least one of an output resistance and an open circuit voltage of the fuel cell power generation unit by using an output voltage obtained based on the first and second electric currents in a state that the cell output acquisition unit allows the fuel cell power generation unit to output the first and second electric currents; and
a degradation judgment unit which judges degradation of the fuel cell power generation unit by using at least one of the output resistance and the open circuit voltage of the fuel cell power generation unit detected by the degradation detection unit.

2. The apparatus according to claim 1, wherein the degradation detection unit obtains an output voltage Va and an output voltage Vb associated with the first and second electric currents in a state that the fuel cell power generation unit is allowed to output the first and second electric currents, and detects at least one of an inclination R(=dv/dI) corresponding to the output resistance of the fuel cell power generation unit which is obtained from a difference voltage dv of the output voltages Va and Vb and a difference current dI of the first and second electric currents and an open circuit voltage OCV obtained from (Va+dv) acquired by adding the voltage difference dv to the output voltage Va.

3. The apparatus according to claim 2, wherein, when a predetermined threshold value is set with respect to at least one of the inclination R and the open circuit voltage OCV detected by the degradation detection unit and the inclination R exceeds the set threshold value or the open circuit voltage OCV falls below the set threshold value, the degradation judgment unit determines the degradation of the fuel cell power generation unit.

4. A fuel cell system comprising:
a fuel cell main body having a fuel cell power generation unit, a fuel reservoir unit that contains a liquid fuel, and a fuel transfer control unit which controls supply of the fuel to the fuel cell power generation unit from the fuel reservoir unit;
a cell output acquisition unit which allows the fuel cell power generation unit to output a first electric current and a second electric current that is double the first electric current;
a degradation detection unit which detects at least one of an output resistance and an open circuit voltage of the fuel cell power generation unit by using an output voltage obtained based on the first and second electric currents in a state that the cell output acquisition unit allows the fuel cell power generation unit to output the first and second electric currents; and
a degradation judgment unit which judges the degradation of the fuel cell power generation unit based on at least one of the output resistance and the open circuit voltage of the fuel cell power generation unit detected by the degradation detection unit,
wherein a fuel supply amount for the fuel cell power generation unit provided by the fuel transfer control unit is controlled in accordance with the degradation judgment made by the degradation judgment unit.

5. The system according to claim 4, wherein the degradation detection unit obtains an output voltage Va and an output voltage Vb associated with the first and second electric currents in a state that the fuel cell power generation unit is allowed to output the first and second electric currents, and detects at least one of an inclination R(=dv/dI) corresponding to the output resistance of the fuel cell power generation unit which is obtained from a difference voltage dv of the output voltages Va and Vb and a difference current dI of the first and second electric currents and an open circuit voltage OCV obtained from (Va+dv) acquired by adding the voltage difference dv to the output voltage Va.

6. The system according to claim 5, wherein, when a predetermined threshold value is set with respect to at least one of the inclination R and the open circuit voltage OCV detected by the degradation detection unit and the inclination R exceeds the set threshold value or the open circuit voltage OCV falls below the set threshold value, the degradation judgment unit determines the degradation of the fuel cell power generation unit and outputs a degradation detection signal.

7. The system according to claim 4, wherein a fuel supply amount for the fuel cell power generation unit provided by the fuel transfer control unit is increased in accordance with the degradation judgment of the degradation judgment unit to control an electric-generating capacity of the fuel cell power generation unit.

8. The system according to claim 4, wherein a fuel supply amount for the fuel cell power generation unit provided by the fuel transfer control unit is reduced in accordance with the degradation judgment of the degradation judgment unit to control an electric-generating capacity of the fuel cell power generation unit.

9. The system according to one of claims 4 to 8, wherein the fuel supply control unit comprises a pump which is used for transferring the fuel to the fuel cell power generation unit or a fuel cutoff valve which enables cutting off supply of a liquid fuel to the fuel cell main body.
